(19) United States
(12) Patent Application Publication
(10) Pub. No.: US 2003/0038339 A1
(43) Pub. Date: Feb. 27, 2003

(54) Semiconductor devices

(76) Inventor: Katsumi Mori, Sakata-shi (JP)

Correspondence Address: KONRAD RAYNES VICTOR & MANN, LLP, 315 SOUTH BEVERLY DRIVE, SUITE 210, BEVERLY HILLS, CA, 90212, US

(21) Appl. No.: 10/202,028

(22) Filed: Jul. 25, 2002

(30) Foreign Application Priority Data
Jul. 25, 2001 (JP) 2001-224688

(51) Int. Cl. H01L 29/00

(52) U.S. Cl. 257/530

(57) ABSTRACT

A semiconductor device may include a fuse section 110 in which a plurality of fuses 20 to be fused by irradiation of a laser beam are formed. The fuses 20 are formed on a first insulation layer 36 and arranged at a specified pitch. Side surfaces and top surfaces of the fuses 20 are covered by a second insulation layer 19.

Applicant claims priority in and hereby incorporates by reference Japanese Application No. 2001-224688 (P), filed Jul. 25, 2001, in its entirety. Applicant hereby incorporates by reference U.S. application Ser. No. ______, filed Jul. 25, 2002, listing Katsumi Mori as inventor, having docket number 15.63/6666, in its entirety. Applicant hereby incorporates by reference U.S. application Ser. No. ______, filed Jul. 25, 2002, listing Katsumi Mori as inventor, having docket number 15.64/6667, in its entirety.

### TECHNICAL FIELD

The present invention relates to semiconductor devices including fuses, and includes semiconductor devices including fuses that may be fused by irradiation of a laser beam.

### RELATED ART

Currently, replacement circuits are built in semiconductor devices in order to substitute for circuits that might become defective due to deficiencies that could occur during the manufacturing process. For example, in the case of a semiconductor memory device, since many of the deficiencies that occur during the manufacturing process would occur in its memory section, multiple redundant memory cells in units of word lines or bit lines are generally disposed therein. A redundant circuit controls the redundant memory cells. When a deficient element is generated in one chip that forms a semiconductor device, the redundant circuit provides a function to switch the deficient element to a normal element by irradiating a laser beam to a fuse element having an address corresponding to the deficient element to thereby fuse (break) the fuse element.

Due to demands in recent years in higher integration of semiconductor devices, memories have been further miniaturized. In connection with this trend, fuse elements themselves have also been miniaturized. Reliability of the fuse elements affects the production yield of semiconductor memory devices, and therefore highly reliable fusing of fuse elements is desired. Improvements in the reliability in fusing fuse elements can improve the production yield of semiconductor devices.

### SUMMARY

Certain embodiments relate to a semiconductor device including a first insulation layer and a plurality of fuses arranged on the first insulation layer at a specified pitch, wherein the fuses are adapted to be fused by irradiation of a laser beam. The device also includes a second insulation layer formed in a manner to cover side surfaces and top surfaces of the fuses.

Certain embodiments also relate to a semiconductor device including a first insulation layer and a plurality of fuses disposed on the first insulation layer, the fuses being adapted to be fused by irradiation of a laser beam, the fuses being spaced apart from each other. The device also includes a second insulation layer formed on and between the fuses.

### BRIEF DESCRIPTION OF THE DRAWINGS

Embodiments of the invention are described with reference to the accompanying drawings which, for illustrative purposes, are schematic and not necessarily drawn to scale.

FIG. 1 schematically shows a cross-sectional view of a semiconductor device in accordance with one embodiment of the present invention.

FIG. 2 schematically shows a plan view of fuses formed in the semiconductor device shown in FIG. 1.

FIG. 3 schematically shows in cross section a step for manufacturing the semiconductor device shown in FIG. 1.

FIG. 4 schematically shows in cross section a step for manufacturing the semiconductor device shown in FIG. 1.

FIG. 5 schematically shows in cross section a step of fusing the fuses conducted on the semiconductor device shown in FIG. 1.

FIG. 6 schematically shows a cross section of fuses that are fused in the step shown in FIG. 5.

### DETAILED DESCRIPTION

A semiconductor device in accordance with certain embodiments of the present invention is characterized in comprising:

a first insulation layer;

a plurality of fuses arranged on the first insulation layer at a specified pitch wherein the fuses are to be fused by irradiation of a laser beam; and

a second insulation layer formed in a manner to cover side surfaces and top surfaces of the fuses.

In accordance with certain embodiments, the film thickness of the second insulation layer may be adjusted according to the material, film thickness and structure of the fuses, whereby stable fusing of the fuses can be conducted. As a result, the production yield can be improved.

The following semiconductor devices in accordance with preferred embodiments of the present invention indicated in sections (1)-(3) below may be listed as examples.

(1) The second insulation layer that covers one of the fuses may preferably be continuous to the second insulation layer that covers another one of the fuses adjacent to the one of the fuses.

(2) The fuses may preferably be formed at a bottom section of an opening section formed on a semiconductor substrate.

(3) The semiconductor device may preferably further comprise a circuit section including a structure of multiple wiring layers, wherein the fuses may be formed in a layer at a level identical with that of one of the wiring layers of the circuit section.

In this case, the fuses may preferably be formed in a layer at a level identical with that of an uppermost wiring layer among the wiring layers that compose the circuit section.

Also, in this case, a film thickness of the fuses may preferably be generally equal to a film thickness of one of the wiring layers that compose the circuit section.

A preferred embodiment of the present invention will be described with reference to the accompanying drawings.

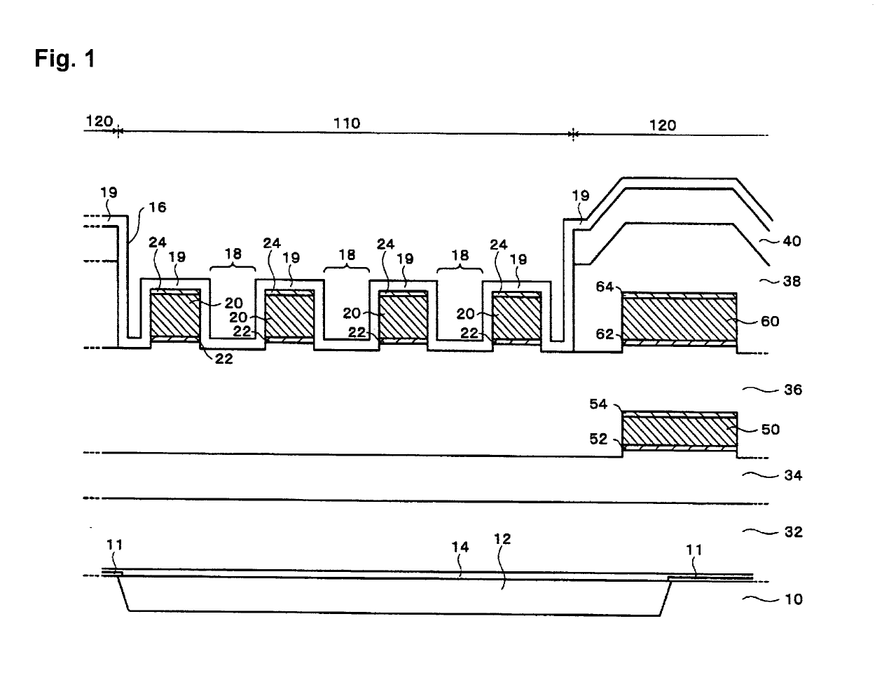

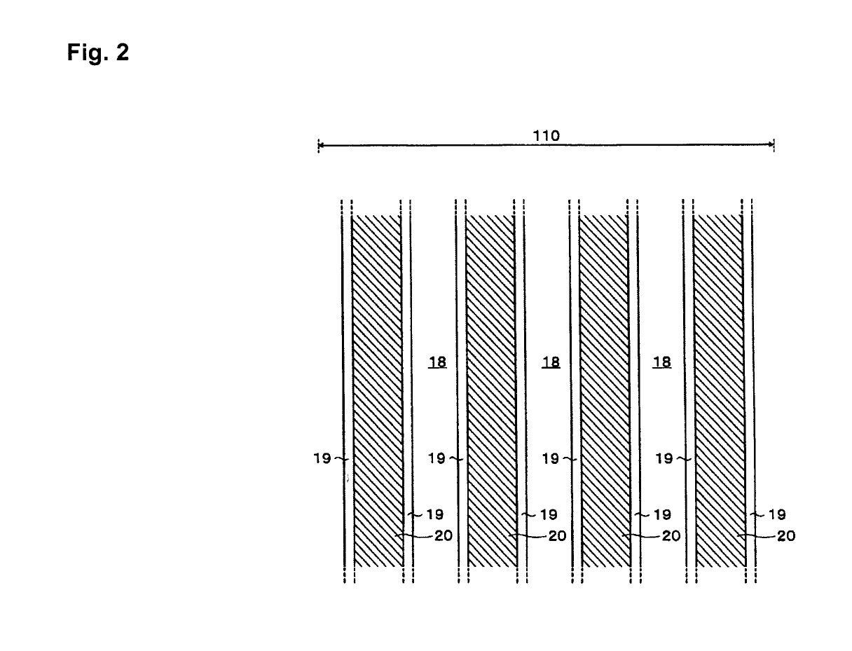

FIG. 1 schematically shows a cross-sectional view of a semiconductor device in accordance with an embodiment of the present invention. FIG. 1 shows a cross section where fuses 20 are cut in a plane perpendicular to a longitudinal direction of the fuses 20. FIG. 2 schematically shows a plan view of the fuses 20 formed in the semiconductor device shown in FIG. 1.

The semiconductor device in accordance with the present embodiment has, as shown in FIG. 1, a circuit section 120 having a structure with multiple wiring layers, and a fuse section 110 including a plurality of fuses 20 that may be fused by irradiation of laser light. It is noted that FIG. 1 shows a structure of the fuses 20 before being fused.

The circuit section 120 and the fuse section 110 are preferably both formed on a silicon substrate 10 that is a semiconductor substrate. First-fourth interlayer dielectric layers 32, 34, 36 and 38 are deposited on the silicon substrate 10 in layers in this order from the side of the silicon substrate 10. The first-fourth interlayer dielectric layers 32, 34, 36 and 38 may preferably be formed from layers of silicon oxide or FSG (fluorinated silicate glass) or layers of these materials. Through holes may be formed in the first-fourth interlayer dielectric layers 32, 34, 36 and 38 at specified locations, respectively. Conductive material may be embedded in the through holes to thereby form contact sections. The contact sections electrically connect wiring layers formed above and below each of the interlayer dielectric layers. Furthermore, a passivation layer 40, which may be formed from, for example, a silicon nitride layer, is preferably formed on the fourth interlayer dielectric layer 38.

The circuit section 120 includes a circuit that includes elements such as transistors. A memory circuit, a liquid crystal driver circuit, and an analog circuit in which capacitors and resistor elements are formed, may also be examples of such a circuit. Also, the memory circuit may include, for example, a DRAM, an SRAM, a flash memory or the like.

In the circuit section 120, multiple wiring layers (FIG. 1 shows only wiring layers 50 and 60) are formed to electrically connect transistors composing memories and other elements included in the circuit section 120. In the semiconductor device shown in FIG. 1, the wiring layer 50 is formed on the second interlayer dielectric layer 34, and the wiring layer 60 is formed on the third interlayer dielectric layer (first insulation layer) 36.

The fuse section 110 is defined by a region including an opening section 16 that is formed over the substrate 10, as shown in FIG. 1. The opening section 16 is formed by etching a specified region of the semiconductor device from the side of the passivation layer 40 to an intermediate section of the fourth interlayer dielectric layer 38. Also, the fuses 20 are formed at a bottom section of the opening section 16.

In the semiconductor device shown in FIG. 1, the fuses 20 are formed in a layer at the same level of the wiring layer 60 formed in the circuit section 120. The wiring layer 60 and the fuses 20 can be formed by the same patterning process. In this case, both of the wiring layer 60 and the fuses 20 are formed on the third interlayer dielectric layer (first insulation layer) 36, have generally the same film thickness, and are formed from the same material. For example, the wiring layer 60 and the fuses 20 can be formed from conductive material, such as, for example, aluminum, copper, polysilicon, tungsten or titanium.

In the semiconductor device of the present embodiment, one case is presented in which the fuses 20 are formed in a layer at the same level of the uppermost wiring layer 60 among the wiring layers that compose the circuit section 120. By virtue of forming the fuses 20 in a layer at the same level of the uppermost wiring layer 60, when the opening section 16 is formed to provide the fuses 20, the amount of the insulation layer to be removed by an etching step can be reduced, and the time required for the etching step can be shortened. It is noted that the position where the fuses 20 may be formed is not limited to a layer at the same level of the uppermost wiring layer 60, and may be formed in a layer at the same level of another wiring layer (for example, in a layer at the same level of the wiring layer 50).

Also, in the semiconductor device shown in FIG. 1, layers of high melting point metal nitride 22 and 24 are formed on bottom surfaces and top surfaces of the fuses 20, respectively. Each of the layers of high melting point metal nitride 22 and 24 is formed from a layer of high melting point metal nitride or a stack of layers of high melting point metal nitride and high melting point metal.

For example, a titanium nitride layer or a stacked layer of titanium and titanium nitride layers may be listed as an example of the layers of high melting point metal nitride 22 and 24. Similarly, layers of high melting point metal nitride 62 and 64 are formed respectively on a bottom surface and a top surface of the wiring layer 60 that comprises the circuit section 120. The layers of high melting point metal nitride 62 and 64 can also be formed by the same process in which the layers of high melting point metal nitride 22 and 24 are formed on the bottom surface and the top surface of the fuses 20. The layers of high melting point metal nitride 62 and 64 act to improve the reliability (such as stress migration resistance and electromigration resistance) of the wiring layer 60. Furthermore, the nitride layer 64 may be used as a reflection preventing film in a photolithography process to process the wiring layer 60.

Furthermore, the wiring layer 50 is formed by a process generally similar to the process in which the fuses 20 and the wiring layer 60 are formed. Accordingly, layers of high melting point metal nitride 52 and 54 are formed at a bottom surface and a top surface of the wiring layer 50, respectively, like the fuses 20 and the wiring layer 60. The layers of high melting point metal nitride 52 and 54 have functions similar to those of the layers of high melting point metal nitride 62 and 64.

The fuses 20 are arranged at a bottom section of the opening section 16 at a specified pitch, as shown in FIGS. 1 and 2. Also, side surfaces and top surfaces of the fuses 20 are covered by a second insulation layer 19. In the semiconductor device of the present embodiment, the layer of high melting point metal nitride 24 is formed on the fuses 20. Accordingly, the top surfaces of the fuses 20 are covered by the second insulation layer 19 through the layer of high melting point metal nitride 24. Also, since the layers of high melting point metal nitride 22 and 24 are formed respectively at the bottom surfaces and the top surfaces of the fuses 20, side surfaces of the layers of high melting point metal nitride 22 and 24 are covered by the second insulation layer 19.

Also, grooves 18 are formed between adjacent ones of the fuses 20. The second insulation layers 19 formed on the respective fuses 20 are formed by the same process. Accordingly, the second insulation layer 19 that covers one of the fuses 20 is continuous with the second insulation layer 19 that covers an adjacent one of the fuses 20.

The second insulation layer 19 comprises, for example, silicon oxide. The second insulation layer 19 is preferably formed on the side surfaces and the top surfaces of the fuses 20 by a CVD method.

In general, an insulation layer formed by a CVD method has a better internal uniformity, compared to an insulation layer formed to a specified film thickness by an etching method. As described above, the second insulation layer 19 is formed by a CVD method, and therefore has a good internal uniformity. Accordingly, there are a fewer variations in the film thickness of the second insulation layers 18 at the respective fuses 20. In general, if the insulation layers formed on the fuses were deviated from one anther in their film thickness, stable fusing of the fuses would become difficult upon fusing the fuses by irradiating a laser beam from the top surface side of the fuses: for example, the fuses may not be fused, or cracks may be generated in the insulation layer around the fuses although the fuses may be blown. In contrast, because the second insulation layer 19 is formed by a CVD method, the second insulation layers have a fewer variations in their thickness among the fuses 20, and thus stable fusing of the fuses 20 can be achieved.

Also, the film thickness of the second insulation layer 19 may be appropriately adjusted in view of the material of the second insulation layer 19, the material and film thickness of the fuses 20, and the output and wavelength of the laser used, to achieve stable fusing of the fuses 20. In particular, by adjusting the film thickness of the second insulation layer 19 depending on the material, film thickness and structure of the fuses 20, the fuses 20 can be stably fused.

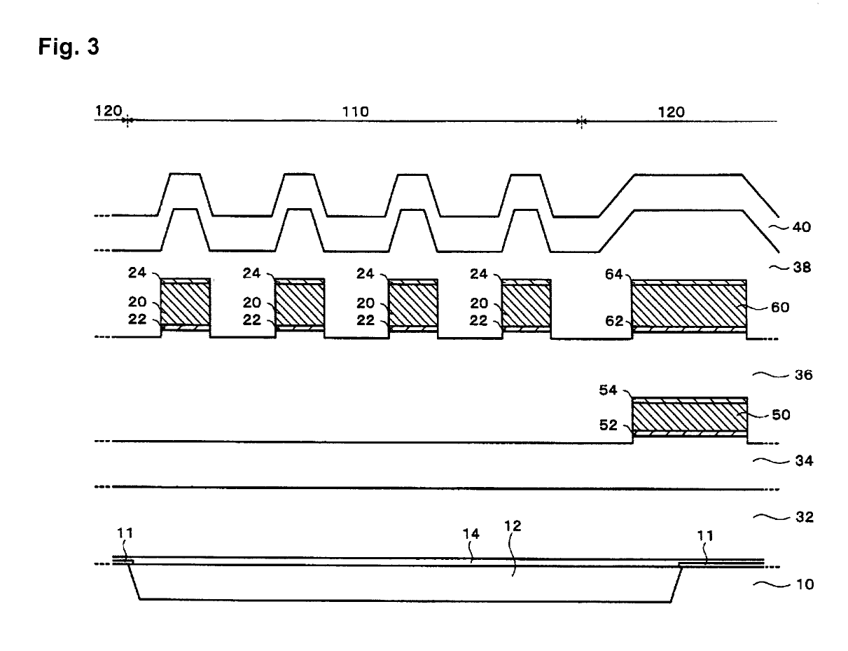

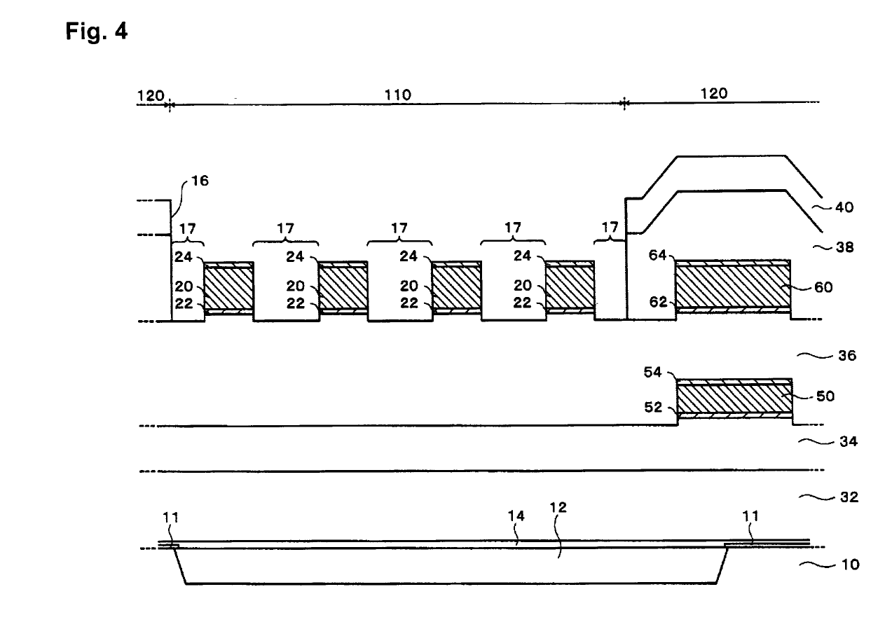

Next, one example of a method for manufacturing the semiconductor device in accordance with the embodiment shown in FIG. 1 will be described with reference to FIG. 3 and FIG. 4. FIG. 3 and FIG. 4 schematically show in cross section steps for manufacturing the semiconductor device shown in FIG. 1.

First, after an element isolation region 12 is formed in a silicon substrate 10, a resist in a specified pattern is formed on the substrate, and then wells are formed at specified locations by an ion implantation. Then, transistors are formed on the silicon substrate 10, and thereafter a silicide layer 11 including high melting point metal such as titanium or cobalt is formed by a known salicide technique. Then, a stopper layer 14 comprising silicon nitride as a main component is formed by a plasma CVD method or the like.

Next, fuses 20 in a fuse section 110 and wiring layers including wiring layers 50 and 60 (only wiring layers 50 and 60 are shown in FIG. 3) in a circuit section 120 are formed, and first-fourth interlayer dielectric layers 32, 34, 36 and 38 are successively deposited in layers. The first-fourth interlayer dielectric layers 32, 34, 36 and 38 may be formed, for example, by an HDP (high density plasma) method, an ozone TEOS (tetraethylorthosilicate) method, or a plasma CVD method, and may be planarized if necessary.

(3) Next, a process for forming fuses 20 is described. The fuses 20 are formed by the same process and in a layer at the same level as those of the wiring layer 60. In other words, the fuses 20 and the wiring layer 60 are formed together on the third interlayer dielectric layer (first insulation layer) 36 with the same material.

First, a layer of high melting point metal nitride such as titanium nitride, a metal layer of aluminum having a specified film thickness, and a stacked layer of a layer of high melting point metal such as titanium and a layer of high melting point metal nitride such as titanium nitride are formed on the third interlayer dielectric layer (first insulation layer) 36 by a sputtering method, and then these layers are patterned in specified shapes. Through these steps, the layers of high melting point metal nitride 22 and 62 are formed from the layer of high melting point metal nitride, the fuses 22 and the wiring layer 60 are formed from the metal layer of aluminum, and the layers of high melting point metal nitride 24 and 64 are formed from the stacked layer of a layer of high melting point metal nitride and a layer of high melting point metal. By this step, the fuses 20 are formed to the same film thickness as that of the wiring layer 60, as shown in FIG. 3.

Then, after the fourth interlayer dielectric layer 38 is formed, a passivation layer 40 composed of silicon nitride or the like is formed on the fourth interlayer dielectric layer 38.

Contact sections for electrically connecting the wiring layers may be formed in each of the interlayer dielectric layers. The contact section is formed through forming a contact hole that passes through each of the interlayer dielectric layers, and a conductive material is embedded in the contact hole by, for example, a sputtering method.

Next, a specified region of the semiconductor device is etched from the side of the passivation layer 40 to an intermediate position in the third interlayer dielectric layer 38, to thereby form an opening section 16, as shown in FIG. 4. In this step, the opening section 16 is formed in a manner that the fuses 20 are located in a bottom section of the opening section 16. Also, in this step, the etching is conducted such that side surfaces and top surfaces of the fuses 20 are exposed. In this step, grooves 17 are formed between adjacent ones of the fuses 20.

Then, a second insulation layer 19 comprising silicon oxide, for example, is formed on the side surfaces and the top surfaces of the fuses 20 by a CVD method, such as, for example, a plasma CVD method, an HDP method or an ozone TEOS method. In other words, the second insulation layer 19 is formed on the side surfaces of the layers of high melting point metal nitride 22 and 24 and the fuses 20, and the top surface of the layer of high melting point metal nitride 24. Here, the film thickness of the second insulation layer 19 may be appropriately adjusted in view of the material of the second insulation layer 19, the material and film thickness of the fuses 20, and the power output and wavelength of the laser used, to achieve stable fusing of the fuses 20. In particular, by adjusting the film thickness of the second insulation layer 19 depending on the material, film thickness and structure of the fuses 20, the fuses 20 can be stably fused.

In the step described above, the second insulation layer 19 is formed by a CVD method, after the side surfaces and the top surfaces of the fuses 20 are etched so that they are exposed. In other words, after the fourth interlayer dielectric layer 38 formed on the side surfaces and the top surfaces of the fuses 20 are removed, as shown in FIG. 4, the second insulation layer 19 having a specified film thickness is formed on the exposed side surfaces and top surfaces of the fuses 20 by a CVD method, as shown in FIG. 1. As a result, the second insulation layer 19 has a fewer variations in its film thickness at the respective fuses 20, and therefore the fuses 20 can be stably fused. The process described above provides the fuses 20 shown in FIGS. 1 and 2.

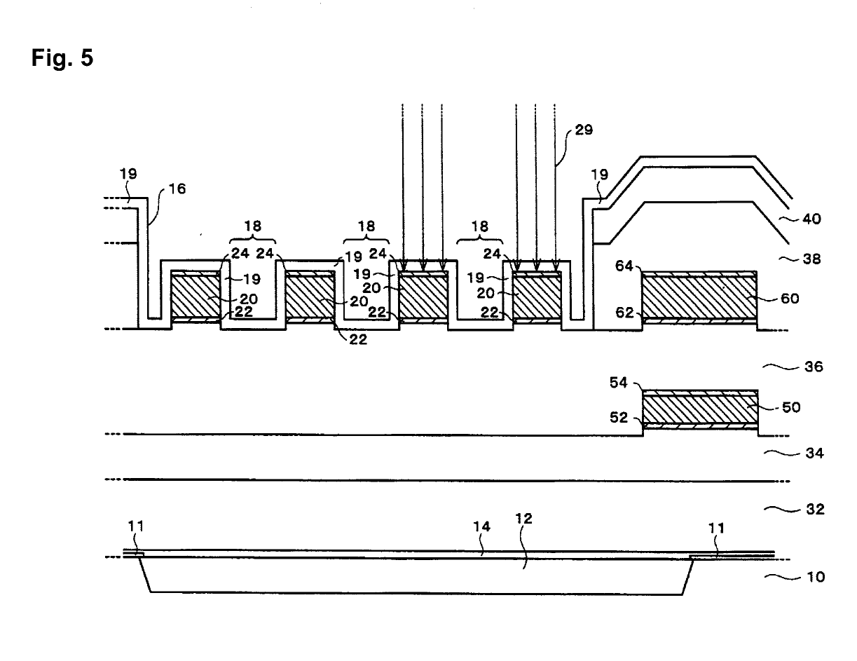

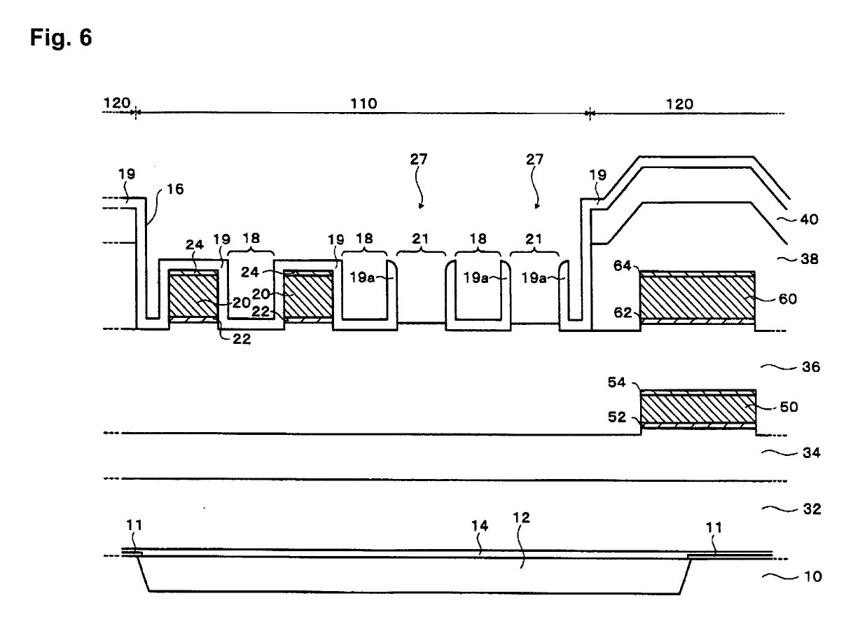

Next, one example of a process for fusing the fuses 20 formed in the semiconductor device obtained by the process shown in FIGS. 3 and 4 will be described with reference to FIGS. 5 and 6. FIG. 5 schematically shows in cross section a step of fusing the fuses 20. FIG. 6 schematically shows a cross section of fuses 27 that are fused.

As shown in FIG. 5, in order to use a redundant memory cell, a laser beam 19 from a laser beam source is irradiated onto each of the corresponding fuses 20. As a result, those of the fuses 20 irradiated by the laser beam 19 are blown. Appropriate wavelength and power of the laser beam may be determined in view of the material and film thickness of the fuses 20, the layer of high melting point metal nitride 24 formed on the top surfaces of the fuses 20, and the second insulation layer 19 formed on the layer of high melting point metal nitride 24.

FIG. 6 schematically shows the fuses 27 that are fused by the step indicated in FIG. 5. When the fuses 20 are fused by the step shown in FIG. 5, the layers of high melting point metal nitride 22 and 24 and portions of the second insulation layer 19 that are formed on the fuses 20 are removed together with the fuses 20. By this step, portions 19a of the second insulation layer 19 are not removed and remain at the blown fuses 27, and grooves 21 are formed at portions where the fuses 20 existed, as shown in FIG. 6.

By the process described above, in the semiconductor device of the present embodiment, since the side surfaces and top surfaces of the fuses 20 are covered by the second insulation layer 19, the fuses 20 can be stably fused for the reasons described above. As a result, the production yield can be improved.

It is noted that the present invention is not limited to the embodiments described above, and many changes can be made within the scope of the present invention.

What is claimed:

1. A semiconductor device comprising:
a first insulation layer;
a plurality of fuses arranged on the first insulation layer at a specified pitch, wherein the fuses are adapted to be fused by irradiation of a laser beam; and
a second insulation layer formed in a manner to cover side surfaces and top surfaces of the fuses.

2. A semiconductor device according to claim 1, wherein the second insulation layer that covers one of the fuses is continuous to the second insulation layer that covers another one of the fuses adjacent to the one of the fuses.

3. A semiconductor device according to claim 1, wherein the fuses are located at a bottom section of an opening section formed in the semiconductor device.

4. A semiconductor device according to claim 1, further comprising a circuit section including a structure of multiple wiring layers, wherein the fuses are formed in a layer at a level identical with that of one of the wiring layers of the circuit section.

5. A semiconductor device according to claim 4, wherein the fuses are formed in a layer at a level identical with that of an uppermost wiring layer among the wiring layers of the circuit section.

6. A semiconductor device according to claim 4, wherein a film thickness of the fuses is generally equal to a film thickness of one of the wiring layers of the circuit section.

7. A semiconductor device according to claim 1, wherein the fuses include a first titanium nitride layer on a lower surface thereof and a second titanium nitride layer on an upper surface thereof.

8. A semiconductor device comprising:
a first insulation layer;
a plurality of fuses disposed on the first insulation layer, the fuses being adapted to be fused by irradiation of a laser beam, the fuses being spaced apart from each other; and
a second insulation layer formed on and between the fuses.

9. A semiconductor device as in claim 8, wherein the fuses include a metal layer sandwiched between layers of material having a higher melting point than the metal layer.

10. A semiconductor device as in claim 8, further comprising a circuit section spaced a distance apart from the plurality of fuses, wherein the circuit section includes a wiring layer having a composition that is the same as that of the fuses.

11. A semiconductor device as in claim 10, wherein the wiring layer and the plurality of fuses are located at an identical level in the semiconductor device.

12. A semiconductor device as in claim 11, wherein the wiring layer is an uppermost wiring layer in the circuit section.

13. A semiconductor device as in claim 10, wherein the wiring layer and the fuses have an identical thickness.

14. A semiconductor device as in claim 8, further comprising an opening formed between adjacent fuses.
